(19) United States
(12) Patent Application Publication
(10) Pub. No.: US 2023/0411211 A1
(43) Pub. Date: Dec. 21, 2023

(54) INTERCONNECT STRUCTURE AND METHOD OF FORMING THE SAME

(71) Applicant: Taiwan Semiconductor Manufacturing Company, Ltd., Hsinchu (TW)

(72) Inventors: Ming-Yang Li, Hsinchu City (TW); Chih-Piao Chuu, Hsinchu City (TW); Szuya Liao, San Jose, CA (US); Han Wang, Hsinchu (TW)

(73) Assignee: Taiwan Semiconductor Manufacturing Company, Ltd., Hsinchu (TW)

(21) Appl. No.: 17/842,804

(22) Filed: Jun. 17, 2022

(51) Int. Cl. H01L 21/768; H01L 23/532

(52) U.S. Cl. CPC H01L 21/76877; H01L 21/76843; H01L 23/53238; H01L 23/53266; H01L 21/76802; H01L 21/7684

(57) ABSTRACT

Provided are an interconnect structure and a method of forming the same. The method includes: forming an opening in a dielectric layer; forming a 2D material layer to conformally cover a surface of the opening; performing a nitridation treatment on the 2D material layer to form a nitrided 2D material layer; forming a metal layer on the nitrided 2D material layer and filling in the opening; and performing a planarization process on the metal layer and the nitrided 2D material layer to expose a top surface of the dielectric layer.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, as multilayer interconnect (MLI) features become more compact with ever-shrinking IC feature size, interconnects of the MLI features are exhibiting increased contact resistance, which presents performance, yield, and cost challenges. It has been observed that higher contact resistances exhibited by interconnects in advanced IC technology nodes can significantly delay signals from being routed efficiently to and from IC devices, such as transistors, negating any improvements in performance of such IC devices in the advanced technology nodes. Accordingly, interconnects still face many challenges to solve.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 6 are cross-sectional views of a method of forming an interconnect structure in accordance with some embodiments.

FIG. 7 is an enlarged cross-sectional view showing a region of FIG. 1 in accordance with some embodiments.

FIG. 8 is an enlarged cross-sectional view showing a region of FIG. 2 in accordance with some embodiments.

FIG. 9A to FIG. 9E are cross-sectional views showing an interconnect structure in accordance with various embodiments.

FIG. 10 is a cross-sectional view showing a semiconductor device with an interconnect structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

IC manufacturing process flow is typically divided into three categories: front-end-of-line (FEOL), middle-end-of-line (MEOL), and back-end-of-line (BEOL). FEOL generally encompasses processes related to fabricating IC devices, such as transistors. For example, FEOL processes can include forming isolation features, gate structures, and source and drain features (generally referred to as source/drain features). MEOL generally encompasses processes related to fabricating contacts to conductive features (or conductive regions) of the IC devices, such as contacts to the gate structures and/or the source/drain features. BEOL generally encompasses processes related to fabricating a multilayer interconnect (MLI) feature that interconnects IC features fabricated by FEOL and MEOL (referred to herein as FEOL and MEOL features or structures, respectively), thereby enabling operation of the IC devices.

As IC technologies progress towards smaller technology nodes, BEOL processes are experiencing significant challenges. For example, advanced IC technology nodes require more compact MLI features, which requires significantly reducing critical dimensions of interconnects of the MLI features (for example, widths and/or heights of vias and/or conductive lines of the interconnects). The reduced critical dimensions have led to significant increases in interconnect resistance, which can degrade IC device performance (for example, by increasing resistance-capacitance (RC) delay). Conventional dual damascene structure includes a conductive feature, a via, and a barrier layer. The conductive feature is disposed on the via. The barrier layer is lined the sidewalls of the conductive feature and the via, and the bottom surface of the via. The conventional barrier layer is composed of a two-layered structure of a tantalum nitride (TaN) layer and a tantalum (Ta) layer, where the TaN layer is used to prevent copper metal from diffusing into the dielectric layer and the Ta layer is used to improve the adhesion between the TaN layer and copper metal. With the shrinking of critical dimensions, the excessively thick barrier layer will hinder the subsequent filling of copper metal, thereby failing to meet the requirements of miniaturization. On the other hand, the resistance value of the conventional barrier layer with high resistance material also significant increases as the critical dimension shrinks, thereby degrading the IC device performance.

In accordance with some embodiments, a two-dimensional (2D) material is used to replace the conventional barrier layer. Next, a nitridation treatment is performed on the 2D material with a semiconductor property to form a nitrided 2D material with a metal conductive property. The nitrided 2D material (e.g., transition metal nitride (TMN) material) may have a thickness less than a thickness of the 2D material and a thickness of the conventional barrier layer (i.e., TaN/Ta layers). The ultra-thin TMN material may make more trench/via space for accommodating to-be-filled metal material, thereby decreasing the contact resistance between the underlying and the overlying conductive features. In the case, the interconnect structure with the nitrided 2D materials as the barrier layer is able to effectively shrink the critical dimension without sacrificing interconnect conductivity, thereby achieving the purpose of miniaturizing devices.

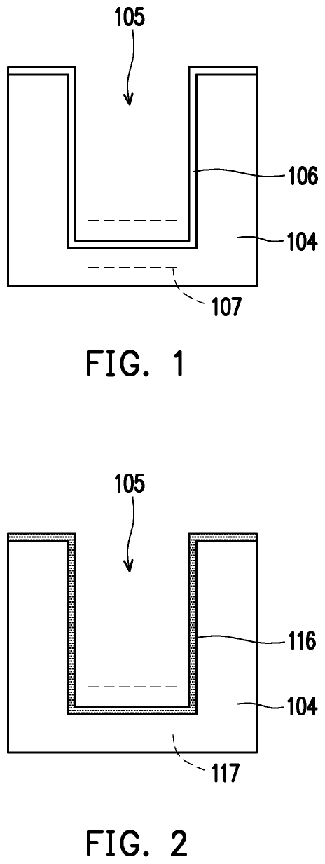

FIG. 1 to FIG. 6 are cross-sectional views of a method of forming an interconnect structure in accordance with some embodiments.

Referring to FIG. 1, a dielectric layer 104 is formed. In some embodiments, the dielectric layer 104 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the dielectric layer 104 includes low-k dielectric materials. Examples of low-k dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. In alternative embodiments, the dielectric layer 104 include one or more dielectric materials. In some embodiments, the dielectric layer 104 is formed by any suitable method, such as chemical vapor deposition (CVD), spin-on, or the like.

After forming the dielectric layer 104, an etching process is performed to remove a portion of the dielectric layer 104, thereby forming an opening 105 in the dielectric layer 104. In some embodiments, the etching process includes a dry etching process, such as a reactive ion etching (RIE) process. As shown in FIG. 1, the opening 105 may be referred to as a via opening with a straight sidewall. However, the embodiments of the present disclosure are not limited thereto. In other embodiments, the opening 105 may have an inclined sidewall, a stepped sidewall, or any shaped sidewall. Although only a single opening 105 is illustrated in FIG. 1, the number of openings may be adjusted according to design requirements.

After forming the opening 105, a 2D material layer 106 is formed to conformally cover the surface of the opening 105 and extend to cover the top surface of the dielectric layer 104. In some embodiments, the 2D material layer 106 includes a transition metal dichalcogenide (TMD) material having a formula MX₂, where M is a transition metal element such as titanium, vanadium, cobalt, nickel, zirconium, molybdenum, technetium, rhodium, palladium, hafnium, tantalum, tungsten, rhenium, iridium, platinum, or a combination thereof, and X is a chalcogen such as sulfur, selenium, tellurium, or a combination thereof. In the specifical embodiment, the TMD material having a formula MX₂, where M is a transition metal element from periodic table column {IVB, VB, VIB}, and X is one element from the group of {S, Se, or Te}. Examples of dichalcogenide materials that are suitable for the 2D material layer 106 include MoS₂, WS₂, WSe₂, MoSe₂, MoTe₂, WTe₂, the like, or a combination thereof. However, any suitable transition metal dichalcogenide material may alternatively be used. It should be noted that the 2D material layer 106 has a better step coverage, so the 2D material layer 106 may be conformally formed on the structured surface of various complex structures and with a uniform thickness. That is, the 2D material layer 106 may be a continuous structure or film to extend on the surface of the opening 105 and the top surface of the dielectric layer 104.

In some embodiments, the 2D material layer 106 is formed by a metal-organic chemical vapor deposition (MOCVD), a molecular team epitaxy (MBE), or an atomic layer deposition (ALD), which has the process temperature lower than 500° C. That is, the process of depositing the 2D material layer 106 is chosen to have the process temperature lower than the thermal budget of the FEOL, MEOL, and/or BEOL process. The term “thermal budget”, as used herein, is used to define an amount of thermal energy transferred (e.g., to a semiconductor wafer during a high-temperature process) and is given as a product of temperature (e.g., in degrees Kelvin) and time (e.g., in seconds). Low thermal budget processes are preferred, for example, to prevent dopant redistribution or electromigration. Moreover, the thermal instability of some high-mobility materials at the high temperatures encountered during typical semiconductor processing may result in relaxation of strained layers (e.g., relaxation of strained Ge layers), increased surface roughness, formation of misfit dislocations, and/or other degradation mechanisms, which can lead to increased carrier scattering, increased resistance, lower mobility, and degraded transistor performance. As used herein, the term “high temperature” refers to temperatures greater than about 500° C., where such temperatures may result in thermal instability and related degradation of high-mobility materials as discussed above. Therefore, the process temperature of depositing the 2D material layer 106 may be lower than 500° C., such as 200° C. to 450° C.

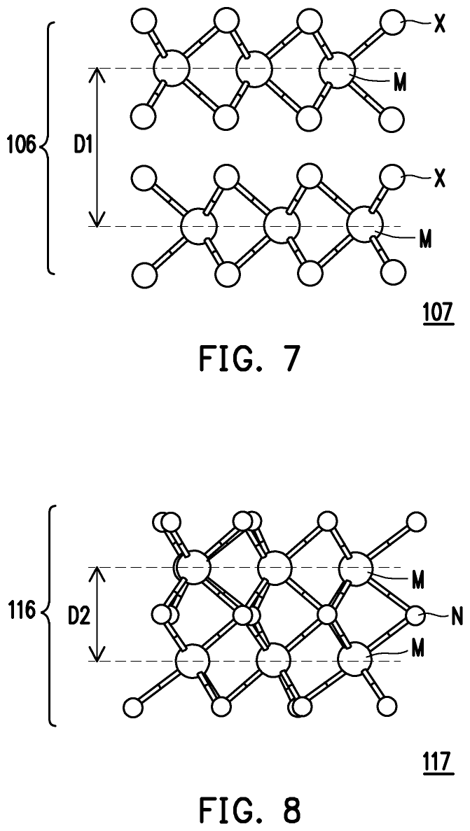

Once formed, the TMD material is in a layered structure with a plurality of two dimensional layers of the general form X-M-X, with the chalcogen atoms in two planes separated by a plane of metal atoms. Specifically, as shown in FIG. 7 which illustrates an enlarged cross-sectional view showing a region 107 of FIG. 1, the layered TMD material can be regarded as stacking two-dimensional X-M-X sandwiches. The bonding within each sandwich layer is of the strong covalent type, giving it outstanding intra-layer strength, while the bonding between the sandwich layers is of the weak van der Waals type. In some embodiments, a shortest distance D1 between the transition metal elements M of two adjacent 2D layers in the 2D material layer 106 is 6.5 Å to 8.5 Å, such as 7.66 Å. Although the 2D material layer 106 illustrated in FIG. 7 only shows two 2D layers of X-M-X, the embodiments of the present disclosure are not limited thereto. In other embodiments, the layer number of 2D layers of X-M-X in the 2D material layer 106 can be controlled by the growth time. That is, the 2D material layer 106 may include a single-layered structure, a two-layered structure, or a multi-layered structure. In some embodiments, a thickness of the 2D material layer 106 is 2 nm to 4 nm, such as 3 nm.

Referring to FIG. 1 and FIG. 2, a nitridation treatment is performed on the 2D material layer 106 to form a nitrided 2D material layer 116. In some embodiments, the nitridation treatment may include exposing the 2D material layer 106 to a nitridation agent or nitridation conditions, so that the transition metal elements in the 2D material layer 106 react with the nitrogen elements to form the nitrided 2D material layer 116. In some embodiments, the nitridation agent may be any suitable nitridation agent including, but not limited to, ammonia (NH₃), hydrazine, NO₂, N₂/Ar plasma, N₂/He plasma, N₂/Ar/He plasma and combinations thereof. In some embodiments, the nitridation conditions comprise a thermal nitridation, plasma-enhanced nitridation, remote plasma nitridation, microwave and radio-frequency (e.g., ICP, CCP).

In the present embodiment, the nitridation treatment is a plasma-enhanced nitridation process. The parameters of the plasma-enhanced nitridation process may be adjusted according to different apparatus are used, which is not limited in the present embodiment. It should be noted that the plasma-enhanced nitridation process is chosen as the said nitridation treatment because the process temperature of the plasma-enhanced nitridation process is less than 500° C., which can prevent the thermal instability and related degradation of high-mobility materials as discussed above due to high thermal budget.

After performing the plasma-enhanced nitridation process, the transition metal elements in the nitrided 2D material layer 116 are bonded together by nitrogen elements, so that the nitrided 2D material layer 116 is configured as a three-dimensional (3D) crystal structure. Specifically, as shown in FIG. 8 which illustrates an enlarged cross-sectional view showing a region 117 of FIG. 2, since the transition metal elements M are chemically bonded together in the stacked direction by the nitrogen elements N, the van der Waals gap/distance D1 (FIG. 7) between two adjacent 2D layers is eliminated. In such embodiment, a shortest distance D2 between the transition metal elements M of two adjacent 2D layers in the nitrided 2D material layer 116 decreases to 2Å-3Å, such as 2.77 Å. Accordingly, a thickness of the nitrided 2D material layer 116 may be decrease to 1 nm-2 nm, such as 1.5 nm. In some embodiments, a ratio of the thickness of the nitrided 2D material layer 116 to the thickness of the 2D material layer 106 is 0.3 to 0.4. It should be noted that the thinned thickness of the nitrided 2D material layer 116 can help the filling capability of the subsequently formed conductive material, so as to achieve the purpose of miniaturizing devices.

In some embodiments, the nitrided 2D material layer 116 includes a transition metal nitride (TMN) material having a formula MN_{y}, wherein M is a transition metal element such as titanium, vanadium, cobalt, nickel, zirconium, molybdenum, technetium, rhodium, palladium, hafnium, tantalum, tungsten, rhenium, iridium, platinum, or a combination thereof, N is a nitrogen element, and y is 0.5 to 2. In the specifical embodiment, the TMD material having a formula MN_{y}, where M is a transition metal element from periodic table column {IVB, VB, VIB}, N is a nitrogen element, and y is 0.5 to 2. Examples of transition metal nitride materials that are suitable for the nitrided 2D material layer 116 include Mo₅N₆, W₅N₆, the like, or a combination thereof. However, any suitable transition metal nitride material may alternatively be used. In the embodiments, the nitrided 2D material layer 116 may be a polycrystalline structure with the transition metal elements M and the nitrogen elements N.

It should be noted that after performing the plasma-enhanced nitridation process, the TMD layer 106 with a semiconductor property is completely nitrided to the TMN layer 116 with a metal conductive property. For example, the MoS₂ layer 106 is fully nitrided to the Mo₅N₆ layer 116. In such embodiment, the formed TMN layer 116 may both have the advantages of thinner thickness and better conductivity to reduce the interconnect resistance, thereby enhancing the device reliability and achieving device miniaturization. In some embodiments, the resistivity of the TMN layer 116 is 80 μΩ·cm to 120 μΩ·cm, and the resistivity of the conventional barrier layer (e.g., TaN or TiN layer) is 100 μΩ·m to 200 μΩ·cm. The resistivity of the TMN layer 116 may be less than the resistivity of the conventional barrier layer. In some embodiments, a ratio of resistivity of the TMN layer 116 (e.g., Mo₅N₆ layer) to the conventional barrier layer (e.g., TaN or TiN layer) is 0.4 to 0.8.

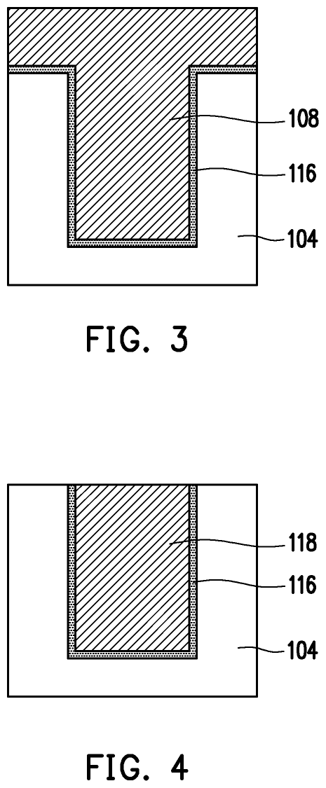

Referring to FIG. 3, a conductive material 108 is formed on the nitrided 2D material layer 116 and filled in the opening 105. In some embodiments, the conductive material 108 may extend from the opening 105 to cover the top surface of the dielectric layer 104. The conductive material 108 may include a seed layer and a metal layer on the seed layer. The seed layer may be a conformal layer lining the sidewalls and the bottom surface of the metal layer. In some embodiments, the seed layer may be a single layer or a composite layer including a plurality of sub-layers formed of different materials. For example, the seed layer is a titanium/copper composited layer. The metal layer may include a metal material, such as Al, Cu, W, Co, Pd, Pt, Ni, other low resistivity metal constituent, an alloy thereof, or a combination thereof, and are formed by an electroplating process.

Referring to FIG. 3 and FIG. 4, a planarization process (e.g., a chemical mechanical polishing (CMP) process) is performed to remove a portion of the conductive material 108 and a portion of the nitrided 2D material layer 116, thereby exposing the top surface of the dielectric layer 104 and forming a conductive feature 118. After performing the CMP process, as shown in FIG. 4, the conductive feature 118 is embedded in the dielectric layer 104, and the nitrided 2D material layer 116 (which may be referred to as barrier layer) extends between the dielectric layer 104 and a bottom surface and a sidewall of the conductive feature 118. In addition, after performing the CMP process, the nitrided 2D material layer 116, the conductive feature 118, and the dielectric layer 104 have substantially planar surfaces.

In some embodiments, the conductive feature 118 may include a metal plug, a metal layer, a metal routing, or a combination thereof to electrically connect the underlying and overlying conductive features. As such, the conductivity of the barrier layer 116 in contact with the conductive feature 118 and the underlying conductive feature (not shown) becomes very important. In the present embodiment, the nitrided 2D material layer 116 has the low resistance comparable to that of the conductive feature 118. Compared with the conventional barrier layer (e.g., TaN/TiN), the contact resistance between the conductive feature 118 and the underlying conductive feature (not shown) is lower to decrease the RC delay and improve the device performance. In addition, compared with the TaN layer or un-nitrided 2D material (e.g., TMD material), the nitrided 2D material layer 116 has the better adhesion with the conductive feature 118 which is comparable with Cu—Cu bonding. That is, the nitrided 2D material layer 116 is in direct contact with the bottom surface and the sidewall of the conductive feature 118 without needing any liner or adhesion layer. In such embodiment, the nitrided 2D material layer 116 having the thinner thickness is suitable for use in the interconnect structures of next generation to achieve the purpose of miniaturizing devices.

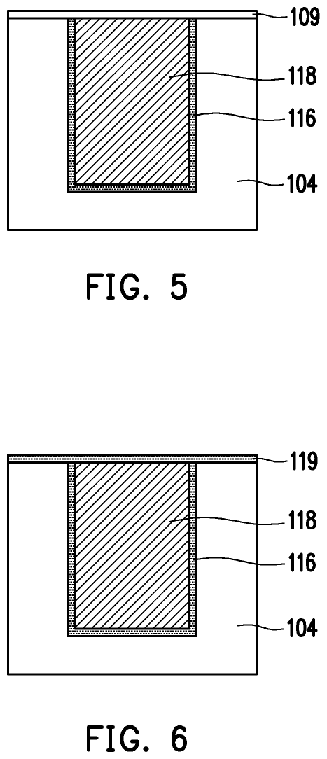

Referring to FIG. 5, a cap layer 109 is formed to cover the conductive feature 118, the nitrided 2D material layer 116, and the dielectric layer 104. The cap layer 109 may protect the underlying conductive feature 118 from oxidation or corrosion. In some embodiments, the cap layer 109 may include a 2D material, a dielectric material, or a combination thereof, and may be formed by any suitable method, such as PECVD, MOCVD, ALD, MBE, or the like. The 2D material may include a transition metal dichalcogenide (TMD) material having a formula MX₂, where M is a transition metal element such as titanium, vanadium, cobalt, nickel, zirconium, molybdenum, technetium, rhodium, palladium, hafnium, tantalum, tungsten, rhenium, iridium, platinum, or a combination thereof, and X is a chalcogen such as sulfur, selenium, tellurium, or a combination thereof. The dielectric material may include silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the dielectric layer 104 includes low-k dielectric materials. Examples of low-k dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. In the example where the cap layer 109 is the dielectric material, the process steps may stay at the structure of FIG. 5. In the example where the cap layer 109 is the 2D material, the process steps may move on next step illustrated in FIG. 6.

Referring to FIG. 5 and FIG. 6, a nitridation treatment is performed on the cap layer 109 to form a nitrided cap layer 119. In some embodiments, the nitridation treatment may include exposing the cap layer 109 to a nitridation agent or nitridation conditions, so that the transition metal elements in the 2D material layer 106 react with the nitrogen elements to form the nitrided cap layer 119. In some embodiments, the nitridation agent may be any suitable nitridation agent including, but not limited to, ammonia (NH₃), hydrazine, NO₂, N₂/Ar plasma, N₂/He plasma, N₂/Ar/He plasma and combinations thereof. In some embodiments, the nitridation conditions comprise a thermal nitridation, plasma-enhanced nitridation, remote plasma nitridation, microwave and radio-frequency (e.g., ICP, CCP).

After performing the nitridation treatment, the transition metal elements in the nitrided cap layer 119 are bonded together by nitrogen elements, so that the nitrided cap layer 119 is configured as a three-dimensional (3D) crystal structure. In some embodiments, the nitrided cap layer 119 includes a transition metal nitride (TMN) material having a formula MN_{y}, wherein M is a transition metal element such as titanium, vanadium, cobalt, nickel, zirconium, molybdenum, technetium, rhodium, palladium, hafnium, tantalum, tungsten, rhenium, iridium, platinum, or a combination thereof, N is a nitrogen element, and y is 0.5 to 2.

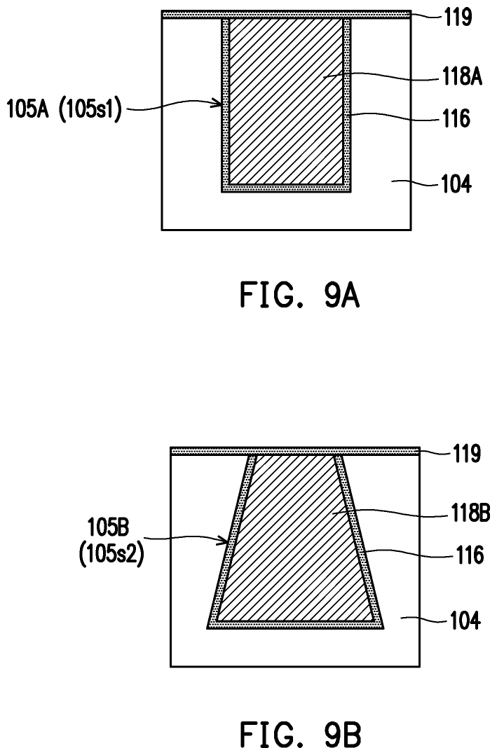

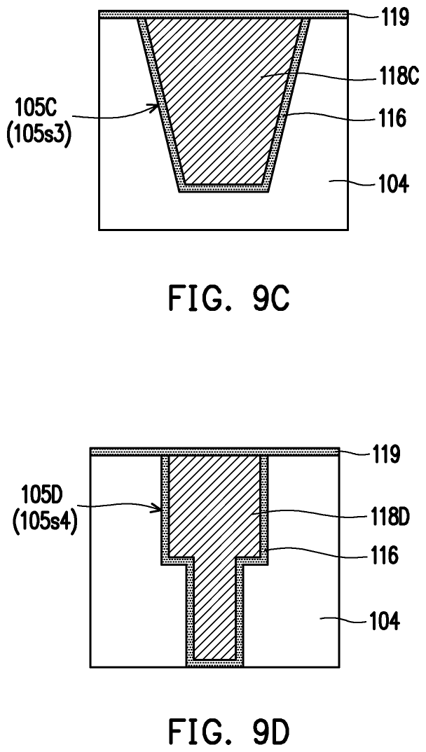

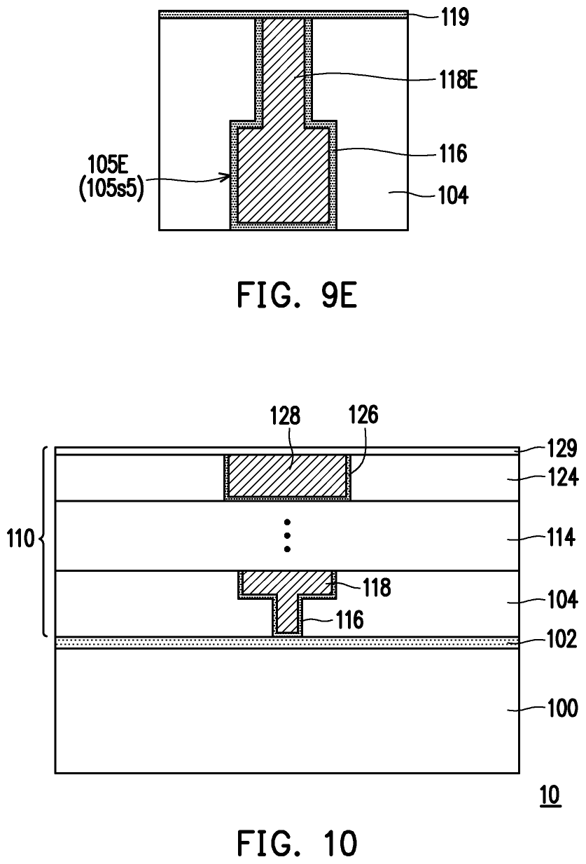

As the shape of the opening in the dielectric layer varies, the conductive feature formed in the opening also has different shapes. FIG. 9A to FIG. 9E illustrate cross-sectional views showing various conductive features, respectively.

Referring to FIG. 9A, an opening 105A formed in the dielectric layer 104 has a straight sidewall 105s1, thus the conductive feature 118A formed in the opening 105A also has a straight sidewall. In such embodiment, the conductive feature 118A has a rectangular shape in cross-sectional view. Referring to FIG. 9B, an opening 105B formed in the dielectric layer 104 has an inclined sidewall 105s2 tapered from bottom to top, thus the conductive feature 118B formed in the opening 105B also has an inclined sidewall tapered from bottom to top. In such embodiment, the conductive feature 118B has a trapezoidal shape in cross-sectional view. Referring to FIG. 9C, an opening 105C formed in the dielectric layer 104 has an inclined sidewall 105s3 tapered from top to bottom, thus the conductive feature 118C formed in the opening 105C also has an inclined sidewall tapered from top to bottom. In such embodiment, the conductive feature 118C has an inverted trapezoidal shape in cross-sectional view. Referring to FIG. 9D, an opening 105D formed in the dielectric layer 104 has a stepped sidewall 105s4, thus the conductive feature 118D formed in the opening 105D also has a stepped sidewall. In such embodiment, the conductive feature 118D has a wider top width and a narrower bottom width in cross-sectional view. In some embodiments, the conductive feature 118D may be referred to as a dual damascene structure. Referring to FIG. 9E, an opening 105E formed in the dielectric layer 104 has a stepped sidewall 105s5, thus the conductive feature 118E formed in the opening 105E also has a stepped sidewall. In such embodiment, the conductive feature 118E has a narrower top width and a wider bottom width in cross-sectional view.

Although five different opening shapes are illustrated in the above paragraphs, the present invention is not limited thereto. In other embodiments, the shape of the opening may be changed according to the lithography process and the etching process. It should be noted that, no matter how complex the shape of the opening is, the 2D material is able to conformally and completely cover the surface of the said opening due to the better step coverage of the 2D material. In such embodiment, the nitrided 2D material layer 116 can also conformally and completely cover the surface of the said opening.

FIG. 10 is a cross-sectional view showing a semiconductor device with an interconnect structure in accordance with some embodiments.

Referring to FIG. 10, a semiconductor device 10 may include a substrate 100, a device region 102, and an interconnect structure 110. In some embodiments, the substrate 100 is a semiconductor substrate, such as a bulk semiconductor, a semiconductor-on-insulator (SOI) substrate, or the like. The substrate 100 may be doped (e.g., with a p-type or an n-type dopant) or undoped. The substrate 100 may be a wafer, such as a silicon wafer. Generally, the SOI substrate is a layer of a semiconductor material formed on an insulator layer. The insulator layer is, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the substrate 100 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or combinations thereof.

In some embodiments, the device region 102 is disposed on the substrate 100 in a front-end-of-line (FEOL) process. The device region 102 may include a wide variety of devices. In some alternative embodiments, the devices include active components, passive components, or a combination thereof. In some other embodiments, the devices include integrated circuits devices. The devices are, for example, transistors, capacitors, resistors, diodes, photodiodes, fuse devices, or other similar devices. In an embodiment, the device region 102 includes a gate structure, source and drain regions, and isolation structures such as shallow trench isolation (STI) structures (not shown). In the device region 102, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed over the substrate 100. The functions of the devices may include memory, processors, sensors, amplifiers, power distribution, input/output circuitry, or the like.

As shown in FIG. 10, the interconnect structure 110 is disposed on the device region 102, and the device region 102 is disposed between the substrate 100 and the interconnect structure 110. In detail, the interconnect structure 110 may include dielectric layers 104, 114, 124, a first conductive feature 118, a second conductive feature 128, and a cap layer 129. The dielectric layers 104, 114, 124 are collectively referred to as an IMD layer, which may be made of a dielectric material, such as silicon oxide, silicon nitride, silicon oxynitride, a spin-on dielectric material, or a low-k dielectric material. The first conductive feature 118 is disposed in the dielectric layer 104 and electrically connected to the device region 102. In some embodiments, the first conductive feature 118 may be referred to as the dual damascene structure which may include a metal plug (via) and a metal line (layer) on the metal plug. It should be noted that the nitrided 2D material layer 116 is formed to extend between the dielectric layer 104 and the bottom surface and the sidewall of the first conductive feature 118. The nitrided 2D material layer 116 may be used to as the barrier layer to prevent the metal atoms (e.g., Cu atoms) of the first conductive feature 118 from diffusing into the IMD layer. In the present embodiment, the nitrided 2D material layer 116 has the thinner thickness, better conductivity, and better adhesion than the conventional barrier layer (e.g., Ta/TaN layers), thus the nitrided 2D material layer 116 is able to reduce the interconnect resistance, thereby enhancing the device reliability and achieving device miniaturization.

In some embodiments, the second conductive feature 128 may be disposed in the dielectric layer 124 and on the first conductive feature 118. The second conductive feature 128 may be electrically connected to the first conductive feature 118. In some embodiments, the second conductive feature 128 may be referred to as the single damascene structure which may include a metal line, a metal layer, or a metal routing. It should be noted that a nitrided 2D material layer 126 is formed to extend between the dielectric layer 124 and the bottom surface and the sidewall of the second conductive feature 128. The material and forming method of the nitrided 2D material layer 126 may be similar to that of the nitrided 2D material layer 116, and have been described in detail in the above paragraphs. The details are thus no repeated herein. The nitrided 2D material layer 126 may be used to as the barrier layer to prevent the metal atoms (e.g., Cu atoms) of the second conductive feature 128 from diffusing into the IMD layer. In the present embodiment, the nitrided 2D material layer 126 has the thinner thickness, better conductivity, and better adhesion than the conventional barrier layer (e.g., Ta/TaN layers), thus the nitrided 2D material layer 126 is able to reduce the interconnect resistance, thereby enhancing the device reliability and achieving device miniaturization.

In some embodiments, the first conductive feature 118 is referred to as the metal 1 (M1), and the second conductive feature 128 is referred to as the metal n (Mn). One or more conductive features may be formed in the dielectric layer 114 between the Mn and the Mn-1. That is, the nitrided 2D material layer may be disposed to line any conductive feature in the back-end-of-line (BEOL) structure, such as M1, M2, M3 or Mn. In such embodiment, the BEOL structure with the nitrided 2D material layer as the barrier layer may have the advantages of low interconnect resistance and small critical dimension to shrink the critical dimension of the interconnect structure, while maintaining the device performance, such as operating speed or the like.

Further, the cap layer 129 may be disposed on the second conductive feature 128. In some embodiments, the cap layer 129 may cover the second conductive feature 128, the nitrided 2D material layer 126, and the dielectric layer 124 to protect the second conductive feature 128 from oxidation or corrosion.

According to some embodiments, a method of forming an interconnect structure includes: forming an opening in a dielectric layer; forming a 2D material layer to conformally cover a surface of the opening; performing a nitridation treatment on the 2D material layer to form a nitrided 2D material layer; forming a metal layer on the nitrided 2D material layer and filling in the opening; and performing a planarization process on the metal layer and the nitrided 2D material layer to expose a top surface of the dielectric layer.

According to some embodiments, a method of forming an interconnect structure includes: forming an opening in a dielectric layer; forming a first material layer to conformally cover a surface of the opening; performing a nitridation treatment on the first material layer with a semiconductor property to form a second material layer with a metal conductive property; and forming a metal plug in the opening, so that the second material layer extends between the dielectric layer and a bottom surface and a sidewall of the metal plug.

According to some embodiments, an interconnect structure includes: a conductive feature embedded in a dielectric layer; and a barrier layer extending between the dielectric layer and a bottom surface and a sidewall of the conductive feature, wherein the barrier layer comprises a nitrified 2D material layer which is in direct contact with the conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming an interconnect structure, comprising:
forming an opening in a dielectric layer;
forming a 2D material layer to conformally cover a surface of the opening;
performing a nitridation treatment on the 2D material layer to form a nitrided 2D material layer;
forming a metal layer on the nitrided 2D material layer and filling in the opening; and
performing a planarization process on the metal layer and the nitrided 2D material layer to expose a top surface of the dielectric layer.

2. The method of claim 1, wherein the 2D material layer comprises a transition metal dichalcogenide (TMD) material having a formula MX₂, wherein M is a transition metal element, and X is a chalcogen.

3. The method of claim 2, wherein the transition metal element comprises titanium, vanadium, cobalt, nickel, zirconium, molybdenum, technetium, rhodium, palladium, hafnium, tantalum, tungsten, rhenium, iridium, platinum, or a combination thereof, and the chalcogen comprises sulfur, selenium, tellurium, or a combination thereof.

4. The method of claim 1, wherein the nitrided 2D material layer comprises a transition metal nitride (TMN) material having a formula MN_{y}, wherein M is a transition metal element, N is a nitrogen element, and y is 0.5 to 2.

5. The method of claim 1, wherein after performing the nitridation treatment, transition metal elements in the nitrided 2D material layer are bonded together by nitrogen elements, so that a thickness of the nitrided 2D material layer is less than a thickness of the 2D material layer.

6. The method of claim 1, wherein a ratio of a thickness of the nitrided 2D material layer to a thickness of the 2D material layer is 0.3 to 0.4.

7. The method of claim 1, wherein the nitridation treatment comprises a plasma-enhanced nitridation process, and a process temperature of the plasma-enhanced nitridation process is lower than 500° C.

8. The method of claim 1, wherein after performing the planarization process, the method further comprises forming a cap layer to cover the metal layer, the nitrified 2D material layer, and the dielectric layer.

9. A method of forming an interconnect structure, comprising:
forming an opening in a dielectric layer;
forming a first material layer to conformally cover a surface of the opening;
performing a nitridation treatment on the first material layer with a semiconductor property to form a second material layer with a metal conductive property; and
forming a metal plug in the opening, so that the second material layer extends between the dielectric layer and a bottom surface and a sidewall of the metal plug.

10. The method of claim 9, wherein the first material layer comprises a transition metal dichalcogenide (TMD) material having a formula MX₂, wherein M is a transition metal element, and X is a chalcogen.

11. The method of claim 9, wherein the second material layer comprises a transition metal nitride (TMN) material having a formula MN_{y}, wherein M is a transition metal element, N is a nitrogen element, and y is 0.5 to 2.

12. The method of claim 9, wherein after performing the nitridation treatment, transition metal elements in the second material layer are bonded together by nitrogen elements, so that a thickness of the second material layer is less than a thickness of the first material layer.

13. The method of claim 9, wherein the nitridation treatment comprises a plasma-enhanced nitridation process, and a process temperature of the plasma-enhanced nitridation process is lower than 500° C.

14. The method of claim 9, wherein a sidewall of the opening comprises a straight sidewall, an inclined sidewall, a stepped sidewall, or a combination thereof.

15. An interconnect structure, comprising:
a conductive feature embedded in a dielectric layer; and
a barrier layer extending between the dielectric layer and a bottom surface and a sidewall of the conductive feature, wherein the barrier layer comprises a nitrided 2D material layer which is in direct contact with the conductive feature.

16. The interconnect structure of claim 15, wherein the nitrided 2D material layer comprises a transition metal nitride (TMN) material having a formula MN_{y}, wherein M is a transition metal element, N is a nitrogen element, and y is 0.5 to 2.

17. The interconnect structure of claim 15, wherein transition metal elements in the nitrided 2D material layer are bonded together by nitrogen elements, so that the nitrided 2D material layer is configured as a three-dimensional (3D) crystal structure.

18. The interconnect structure of claim 15, wherein a shortest distance between the transition metal elements in two adjacent layers is 2Å to 3 Å.

19. The interconnect structure of claim 15, wherein the conductive feature comprises a metal plug, a metal layer, a metal routing, or a combination thereof.

20. The interconnect structure of claim 15, wherein a thickness of the nitrided 2D material layer is 1 nm to 2 nm.
